(19) United States
(12) Patent Application Publication
(10) Pub. No.: US 2010/0332950 A1
(43) Pub. Date: Dec. 30, 2010

(54) BIT ERROR THRESHOLD AND CONTENT ADDRESSABLE MEMORY TO ADDRESS A REMAPPED MEMORY DEVICE

(76) Inventors: Gurkirat Billing, Lincoln, CA (US); Stephen Bowers, Woodland, CA (US)

Correspondence Address: Berkeley Law & Technology Group LLP, 17933 NW Evergreen Parkway, Suite 250, Beaverton, OR, 97006, US

(21) Appl. No.: 12/494,950

(22) Filed: Jun. 30, 2009

(51) Int. Cl. H03M 13/09; G06F 12/02

(52) U.S. Cl. 714/768; 711/108; 714/E11.04; 711/E12.007

(57) ABSTRACT

Subject matter disclosed herein relates to remapping memory devices.

### BACKGROUND

1. Field

Subject matter disclosed herein relates to remapping memory devices.

2. Information

Memory devices are employed in many types of electronic devices, such as computers, cell phones, PDA's, data loggers, and navigational equipment, just to name a few examples. Among such electronic devices, various types of nonvolatile memory devices may be employed, such as NAND or NOR flash memories, SRAM, DRAM, and phase-change memory, just to name a few examples. In general, writing or programming processes may be used to store information in such memory devices, while a read process may be used to retrieve stored information.

Such nonvolatile memory devices may comprise memory cells that slowly deteriorate over time, leading to an increasing probability that a read and/or write error may occur upon accessing such a memory cell. Though such errors may be subsequently corrected within a memory device, for example, such error correction may become difficult or impossible as the number of errors increases.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIG. 1 is a schematic view of a memory configuration, according to an embodiment.

FIG. 2 is a flow diagram of a memory remap process, according to an embodiment.

FIG. 3 is a flow diagram of a memory remap process, according to another embodiment.

FIG. 4 is a schematic view of a vector remap table, according to another embodiment.

FIG. 5 is a schematic block diagram of a memory system, according to an embodiment.

FIG. 6 is a schematic block diagram of a memory system, according to another embodiment.

FIG. 7 is a schematic block diagram of a computing system and a memory device, according to an embodiment.

### DETAILED DESCRIPTION

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

In an embodiment, a memory device may comprise memory cells that slowly deteriorate over time, which may lead to an increased probability that one or more errors may occur while reading such a memory device. Such errors may be corrected in several areas within a computing system, for example, using error correction codes (ECC) or other such algorithms. From a system perspective, a determination may be made as to whether or not to continue to utilize such error-prone cells. As will be explained in further detail below, such a determination may be based, at least in part, on a comparison of the number of such errors to an error threshold, which may be defined during a design stage of a memory device, for example. In one implementation, use of particular memory cells may be discontinued before such cells display an excess number of errors. In other words, use of error-prone memory cells may be discontinued if such memory cells produce a number of errors that approaches an error threshold. Such a threshold need not be reached, for example, in order to determine that use of memory cells may be discontinued. Accordingly, observing a number of errors approaching an error threshold may be a way to predict that particular memory cells may soon produce too many errors, so use of such error-prone memory cells may be stopped before the memory cells actually begin to critically malfunction, for example. If use of particular memory cells is to be discontinued, then replacement memory cells may be selected in a manner that maintains an overall memory device capacity.

Accordingly, in one embodiment, a process to maintain a size capacity of a memory device may include remapping an error-prone memory location to a properly functioning memory location, without a loss of overall system memory space (e.g., storage device capacity). Such remapping may be based, at least in part, on information regarding a quantity and/or frequency of errors occurring as a result of reading from an error-prone memory location. Here, memory location refers to a portion of a memory device that may be accessed, e.g., via a read and/or write process, using an address or addresses to identify such a memory location and/or portion. As explained in further detail below, an ECC decoder, for example, may be used to determine a bit error rate and/or the number of bit errors associated with reading a particular portion of a memory. Subsequently, the bit error rate and/or number of bit errors may be compared to an error threshold, which may comprise a substantial limit to an acceptable number of errors, for example. Depending on an outcome of such a comparison, a decision may be made regarding whether to retire, e.g., discontinue use of, the particular portion of memory producing the errors.

In a particular embodiment, a process of retiring a portion of a memory device may include moving signals representative of data stored in the to-be-retired portion of the memory device to another portion of the memory device. In one implementation, such data relocated from a retired portion of a memory device may be moved to a spare portion of the memory device. For example, such a spare portion of memory may include a physical location of the memory device not initially recognized or considered as part of the full capacity of the memory device, as explained in more detail below. A process of retiring a portion of a memory device may also include remapping an address of a to-be-retired portion of the memory device to correspond to an address of a new, spare portion of the memory device. Such remapped addresses may be stored in a content-addressable memory (CAM), for example, as explained in detail below. Of course, such processes are merely examples, and claimed subject matter is not so limited.

In one embodiment, a process such as that described above may involve a memory device comprising a phase-change memory (PCM) device. Accordingly, as a PCM ages, a bit error rate and/or a number of bit errors produced by portions of the PCM may increase. Such errors, to some extent, may be corrected using an ECC decoder and/or other such error correcting algorithms, for example. However, a number of errors may increase beyond a capability of such error-correcting techniques. Therefore, it may be desirable to retire such memory portions upon an indication of a trend that such memory portions have been or are beginning to produce an excessive number of errors.

Embodiments, such as those described above, may allow successful use of storage devices involving relatively less reliable technologies. For example, die previously considered unusable may be employed using embodiments described herein. Also, such embodiments may extend a lifetime of a storage device to that of a majority of its memory cells rather than the life of a relatively few of its memory cells.

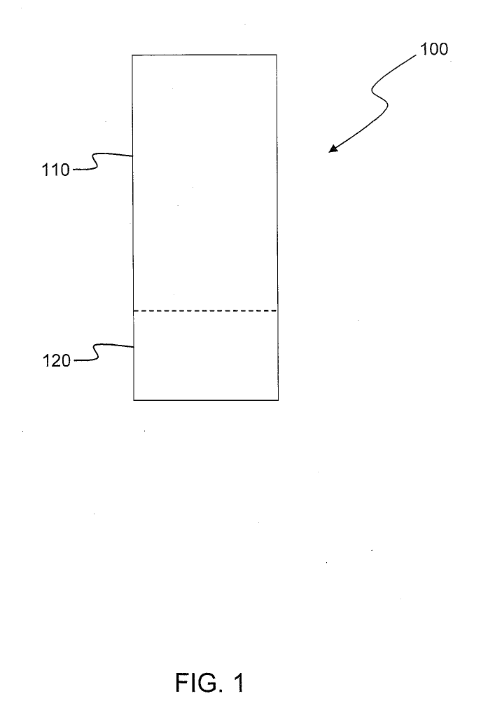

FIG. 1 is a schematic view of a memory configuration, according to an embodiment. A memory device 100 may be partitioned into a main memory 110 and a spare memory 120. Memory device 100 may comprise NAND or NOR flash memories, SRAM, DRAM, or PCM, just to name a few examples. Memory device 100 may comprise a user-addressable memory space including such main and spare memory portions and/or one or more other memory portions, which may or may not be contiguous with one another, and may or may not reside on a single device. Main memory 110 and spare memory 120 may comprise independent addressable spaces that may be accessed by read, write, and/or erase processes, for example.

According to an embodiment, one or more portions of memory device 100 may store signals representative of data and/or information as expressed by a particular state of memory device 100. For example, an electronic signal representative of data and/or information may be “stored” in a portion of memory device by affecting or changing the state of such portions of memory device 100 to represent data and/or information as binary information (e.g., ones and zeros). As such, in a particular implementation, such a change of state of the portion of memory to store a signal representative of data and/or information constitutes a transformation of memory device 100 to a different state or thing.

Memory device 100 may be configured to initially comprise main memory 110 corresponding to the fully usable capacity of memory device 100. Such an initial configuration may additionally comprise spare memory 120 that need not be included in determining memory device capacity. However, if portions of main memory become unusable or result in an excess number of errors during read/write processes, for example, spare memory 120 may be used to replace portions of main memory 110. Of course, details of such a memory configuration are merely examples, and claimed subject matter is not so limited.

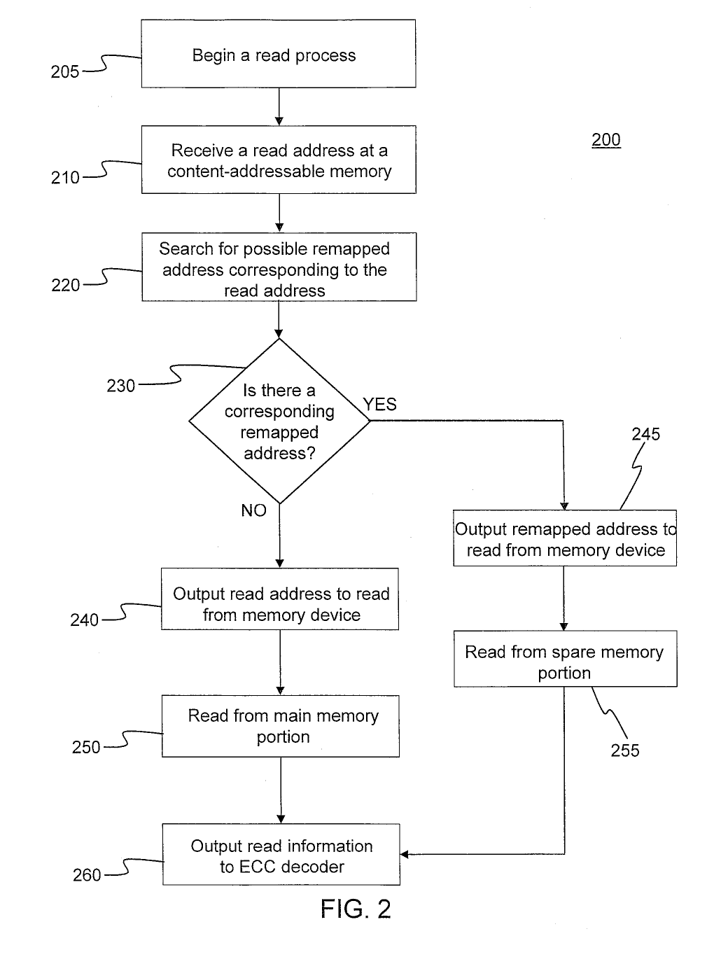

FIG. 2 is a flow diagram of a memory read process 200, according to an embodiment. At block 205, a read process to read a portion of a memory device may be initiated, for example, by a system application that provides one or more read addresses to respectively identify one or more memory locations from where stored data is to be read. At block 210, one or more such read addresses may be provided to a CAM, for example, where a search may be conducted for possible remapped addresses corresponding to the provided read addresses. In one implementation, a CAM may store a database and/or table that associates original addresses with corresponding remapped addresses. Accordingly, by searching such a CAM, a determination may be made, at block 230, whether an incoming original read address is associated with a corresponding remapped address in the CAM. If not, wherein a search for a remapped address associated with a particular original read address returned a null result, then read process 200 may proceed to block 240, where the original read address may be output. As a result, at block 250, the original read address may be used to read from a memory device. Subsequently, at block 260, data read from the original read address of the memory device may be provided to error-checking hardware and/or software, such as an ECC decoder and/or other such error correcting algorithms, for example.

On the other hand, if a determination is made, at block 230, that an incoming original read address has a corresponding remapped address, then read process 200 may proceed to block 245, where a remapped address corresponding to a particular original read address may be transmitted. As a result, at block 255, the remapped read address may be used to read from a memory device. In one implementation, a spare portion of the memory device may be read from if a remapped address is utilized, but such a limitation is merely an example. Subsequently, at block 260, data read from the remapped read address of the memory device may be provided to error-checking hardware and/or software, such as an ECC decoder and/or other such error correcting algorithms, for example. Of course, details of such a memory read process are merely examples, and claimed subject matter is not so limited.

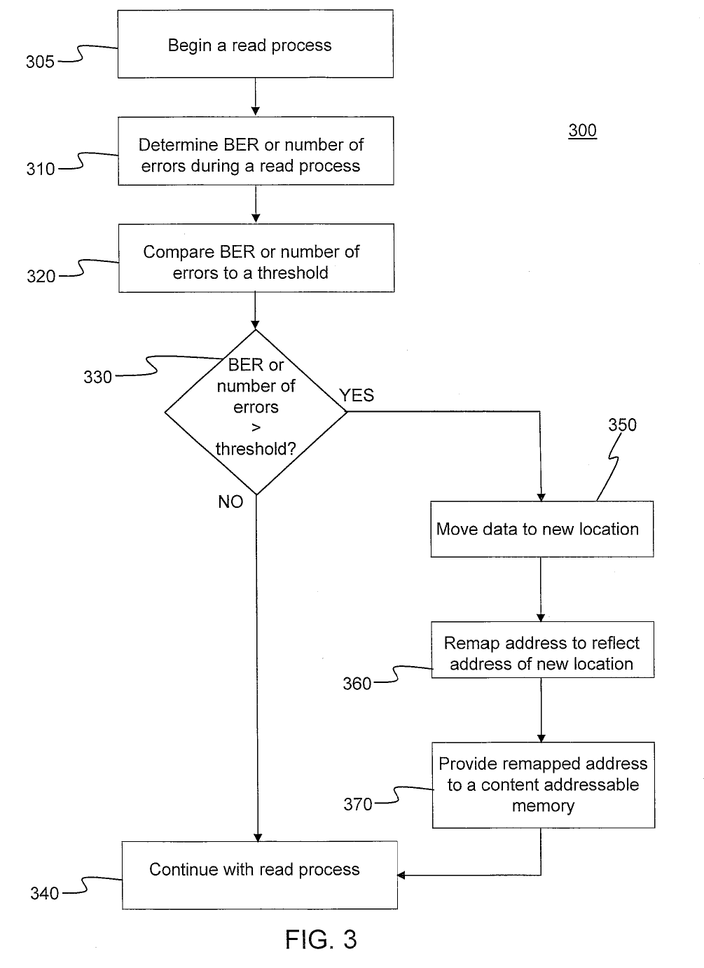

FIG. 3 is a flow diagram of a memory read process 300, according to an embodiment. At block 305, a read process to read signals representative of information stored in a portion of a memory device may be initiated, for example, by a system application that provides one or more read addresses to respectively identify one or more memory locations from where stored signals representative of data is to be read. ECC hardware and/or software, by parity checking read data for example, may be used to check and/or correct errors in read data. Subsequently, initially read data may be compared to corrected read data, thus determining the number of errors that occurred in the memory read process, as at block 310. In one particular implementation, such a number of errors may be expressed as a bit error rate (BER), which may comprise a ratio of the number of error bits to the total number of read bits, for example. At block 320, a BER or number of errors resulting from reading from a portion of a memory device may be compared to an error threshold value, which may comprise a value that represents a maximum acceptable BER or maximum acceptable number of errors, beyond which, for example, additional errors may not be successfully corrected: such an error threshold value may comprise a number that represents a substantially upper limit of a BER or a number of errors that are acceptable for a particular memory device, such as memory device 100 shown in FIG. 1, for example. At or below such an error threshold value, ECC hardware and/or software may be capable of correcting read errors. But above such an error threshold, there may be a relatively high probability that at least some read errors may not be correctable.

At block 330, a decision is made as to whether to retire a portion of a memory device based at least in part on whether reading from such a portion of memory results in too many errors. If such a number of errors is at or below an error threshold, then read process 300 may proceed to block 340 where, for example, read data may be provided to an application that requested the read data. On the other hand, if such a number of errors is above an error threshold, then read process 300 may proceed to block 350, where, for example, a process may begin to retire a portion of memory that leads to too many errors. In a particular implementation, data initially stored in such an error-prone memory portion may be moved to another memory portion that is known to be functional and/or healthy. Such a new memory portion may comprise a portion of spare memory, such as spare memory 120 shown in FIG. 1, for example. At block 360, a memory address, or multiple memory addresses, to identify the original memory location(s) of the data may be remapped to identify the new memory portion to where data is relocated. In one implementation, remapping may comprise assigning a new address to correspond, via a vector for example, to an original address so that a call to the original address may be redirected to a new address specifying the location of relocated data. At block 370, information regarding such remapped addresses may then be provided to a CAM, which may maintain such information in a vector remap table, described in detail below. After remapping an error-prone portion of memory, read process 300 may proceed to block 340, wherein read data may be provided to an application that requested the read data, for example. Of course, details of such a memory read process are merely examples, and claimed subject matter is not so limited.

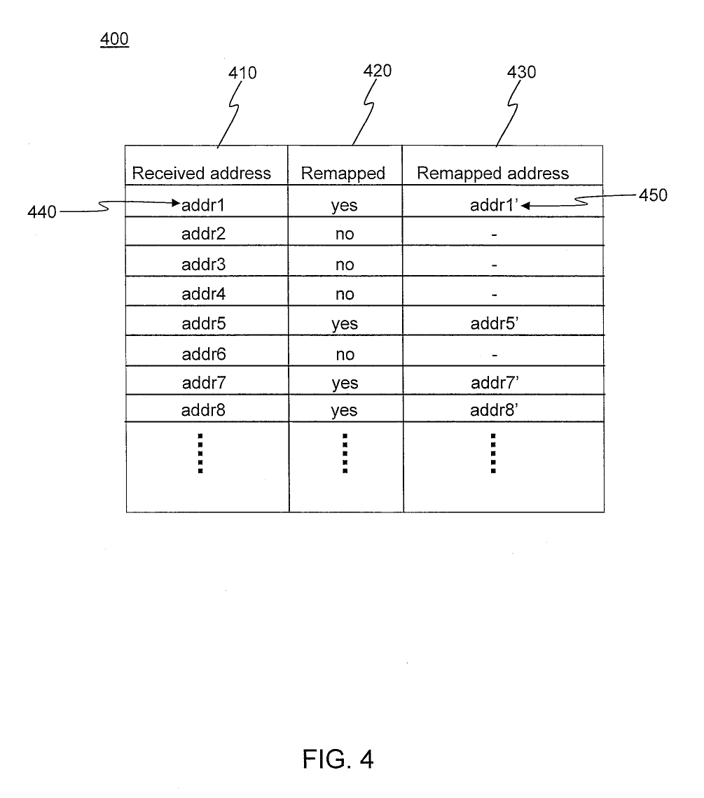

FIG. 4 is a schematic view of a vector remap table 400, according to an embodiment. Information included in table 400, in other implementations, need not be formatted in a table; such information, for example, may comprise an array or other means for organizing such information. Such information may be stored as signals in a CAM, for example. Column 410 may comprise a list of original addresses 440, such as addr1, addr2, addr3, and so on; status column 420 may comprise information regarding whether a corresponding original address listed in column 410 has been remapped; and column 430 may comprise a list of remapped addresses 450, such as addr1′, addr2′, addr3′, and so on, corresponding to original addresses 440, listed in column 410.

In one implementation, original addresses 440 may comprise one or more addresses included in a read request by an application and/or system inquiring about information stored in memory device 100 at the location of the one or more addresses. Status column 420 may comprise metadata to describe whether an original address 440 has been remapped. If such remapping has occurred, then column 430 may comprise a remapped address 450 corresponding to an original address 440. To illustrate by an example according to FIG. 1, addr1, addr5, addr7, and addr8 have been remapped to addr1′, addr5′, addr7′, and addr8′, respectively, while addr2, addr3, addr4, and addr6 have not been remapped. Here, original addresses that have not been remapped have no corresponding remapped address in column 430. In another implementation, status column 420 need not be included in table 400 since a presence of a remapped address 450 may be sufficient to indicate that remapping has occurred for a particular original address 440, for example. Of course, details of such a vector remap table and other formats of storing remap information are merely examples, and claimed subject matter is not so limited.

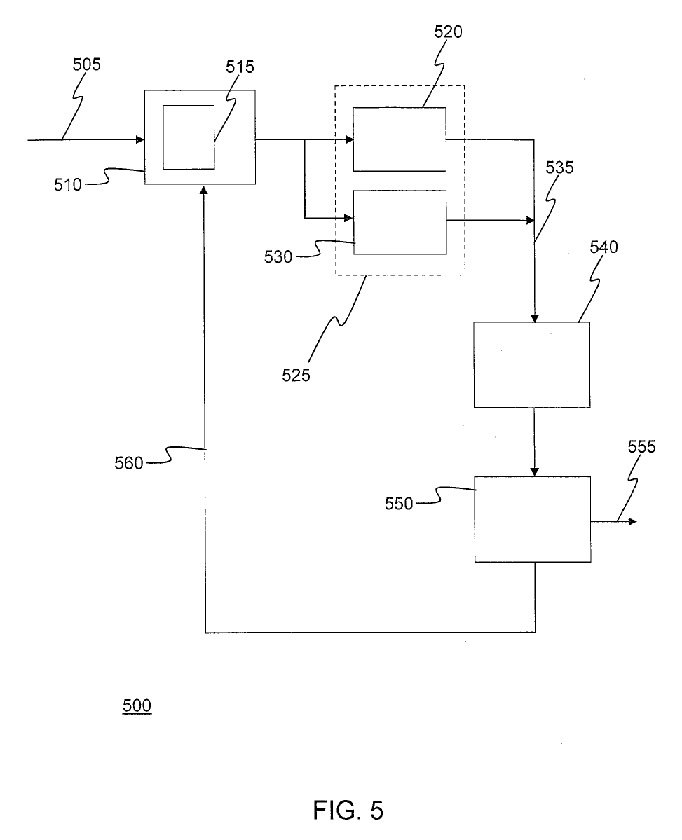

FIG. 5 is a block diagram of a memory system 500, according to an embodiment. A controller 510 may be configured to receive one or more signals indicative of a read request 505 that comprises an address specifying a location of a memory device 525 from which to read data. Memory device 525 may comprise main memory 520 and spare memory 530, as described above, for example. Incoming addresses accompanying read requests may be passed through a CAM 515, where such addresses may be compared to contents stored in CAM 515, which may comprise remapped addresses associated with original addresses. In one particular implementation, remapping processes occur without particular instructions and/or signals generated by a user at a system level, so that incoming addresses accompanying read requests may always comprise original addresses; such addresses may be associated with their associated remapped addresses subsequent only to a CAM search. In other words, CAM 515 may provide a translation from an original address space to a remapped address space. In such a fashion, controller 510 may determine whether read request 505 comprises an address that has been remapped. Depending on such a determination, controller 510 may direct read request 505 to either main memory 520 or spare memory 530 to read data. For example, if the address of read request 505 has not been remapped, then controller 510 may forward the read request to main memory 520, whereas if such an address has been remapped, then controller 510 may modify read request 505 to comprise a remapped address that may be directed to spare memory 530. Subsequently, either main memory 520 or spare memory 530 may provide read data 535 to an error detection block 540, which may comprise an error counter and/or an ECC decoder, for example. In one embodiment, error detection block 540 comprising an ECC decoder may be disposed in a die element of memory device 525. In another embodiment, error detection block 540 comprising an ECC decoder may be provided at a system level, such as in an application, for example. Error detection block 540 may detect and/or correct any errors present in read data 535, and may express such detected errors as a BER and/or number of bit errors. Accordingly, error detection block 540 may provide corrected read data 545 to an entity that introduced read request 505, such as an application and/or host system. Error detection block 540 may also provide information regarding the number of errors present in read data 535 to a compare engine 550. In the case where error detection block 540 comprises an ECC decoder disposed in a die element of memory device 525, such error information may be accessible by a compare engine application at a system level. In one implementation, for example, an ECC decoder may include an error information register available for access by compare engine 550, which may compare the number of detected errors to an error threshold.

As explained above, such an error threshold may comprise a maximum acceptable BER or number of errors. Compare engine 550 may provide results 560 of such a comparison to controller 510. Based at least in part on such comparison results, controller 510 may determine whether to retire a particular portion of memory device 525. If such a comparison indicates that a particular portion of memory device 525 resulted in an excess number of bit errors during a read process, for example, then controller 510 may initiate a process to retire the error-prone portion of memory. Such a retiring process may include relocating data stored in the retiring portion of memory to another portion of memory. For example, data may be moved from a particular portion of main memory 520 to spare memory 530. Accordingly, controller 510 may modify an address that identified the retiring portion of memory to an address that identifies the new portion of memory to contain the relocated data. Such a modified, remapped address may then be written into CAM 515, where it may be associated with the original address, as described above. Such a memory retiring process may occur seamlessly with respect to an application and/or host system that introduced read request 505, for example. Of course, such an implementation of a memory system is merely an example, and claimed subject matter is not so limited.

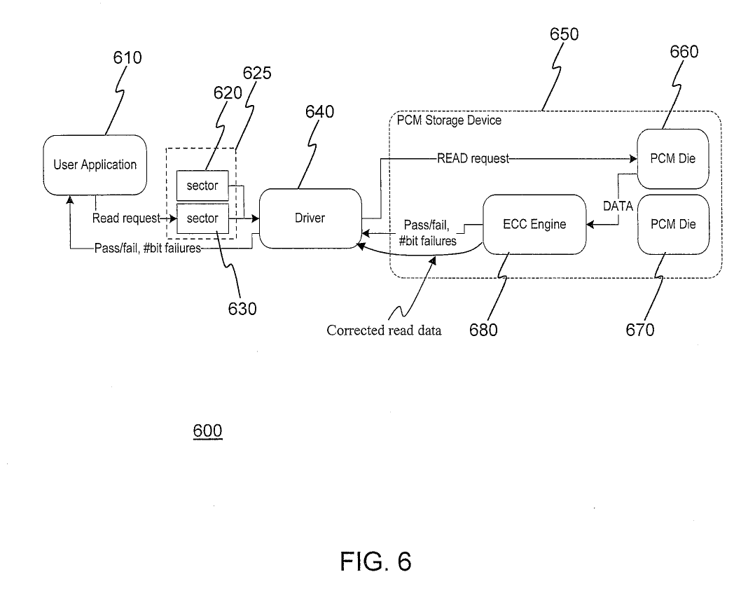

FIG. 6 is a block diagram of a memory system 600, according to an embodiment. A user application 610 may be configured to provide a read request to driver 640. In one implementation, user application 610, CAM 625, and/or driver 640 may comprise software, such as instructions that may be executed by one or more special purpose processors to carry out one or more processes described below, for example. In contrast, storage device 650 may comprise hardware, though claimed subject matter is not so limited.

In an embodiment, user application 610 may provide an original read address that is provided to a CAM 625 comprising a sector 620 listing original read addresses and a sector 630 listing corresponding remapped read addresses, for example. Accordingly, CAM 625 may output a read request comprising an original read address or a remapped read address, depending, at least in part, on whether a particular read address has been remapped. Subsequently, driver 640 provides such an address to a PCM storage device 650 specifying a location of the storage device from which to read data. Storage device 650 may comprise main PCM die 660 and spare PCM die 670, as described above, for example. Either portion of PCM storage device 650 may be read from, depending, at least in part, on an address provided by driver 640, for example.

Subsequently, either main PCM die 660 or spare PCM die 670 may provide read data to an ECC engine 680, which may comprise an error counter and/or an ECC decoder, for example. In one embodiment, ECC engine 680 may be disposed in a die element of PCM storage device 650. ECC engine 680 may detect and/or correct any errors present in read data, and may express such detected errors as a BER and/or number of bit errors per code word and/or per accessed chunk of data, for example. Accordingly, ECC engine 680 may provide corrected read data to user application 610, and also provide information regarding the number of errors present in read data to driver 640. In turn, driver 640 may provide a number of detected errors to user application 610, for example. Based at least in part on the number of such errors, user application 610 may determine whether to retire a particular portion of PCM storage device 650 using one or more processes described above, for example. Of course, such an implementation and configuration of a memory system is merely an example, and claimed subject matter is not so limited.

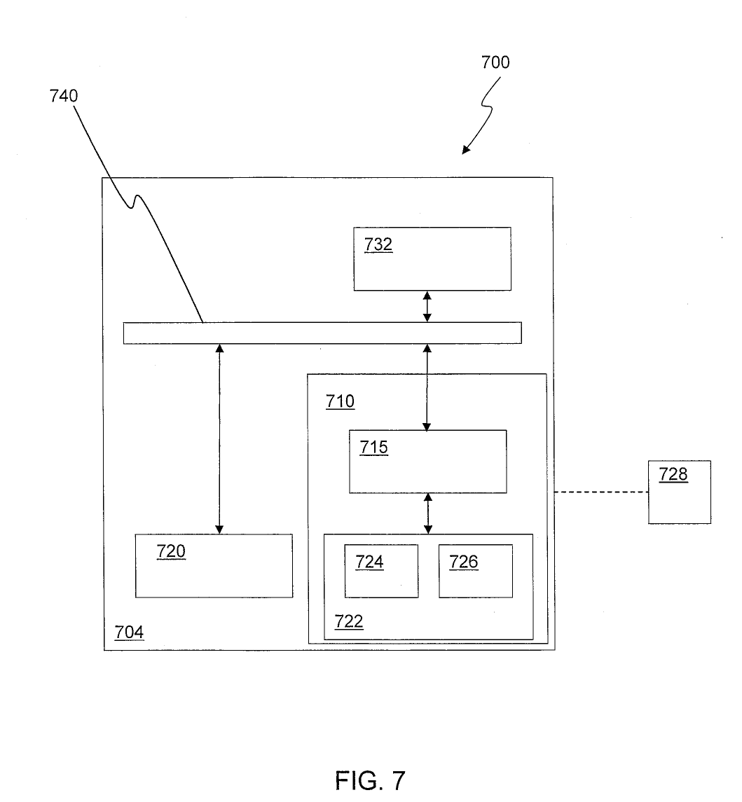

FIG. 7 is a schematic diagram illustrating an exemplary embodiment of a computing system 700 including a memory device 710, which may be partitioned into main and spare portions as discussed above, for example. A computing device 704 may be representative of any device, appliance and/or machine that may be configurable to manage memory device 710. Memory device 710 may include a memory controller 715 and a memory 722. By way of example but not limitation, computing device 704 may include: one or more computing devices and/or platforms, such as, e.g., a desktop computer, a laptop computer, a workstation, a server device, or the like; one or more personal computing or communication devices or appliances, such as, e.g., a personal digital assistant, mobile communication device, or the like; a computing system and/or associated service provider capability, such as, e.g., a database or data storage service provider/system; and/or any combination thereof.

It is recognized that all or part of the various devices shown in system 700, and the processes and methods as further described herein, may be implemented using or otherwise including hardware, firmware, software, or any combination thereof. Thus, by way of example but not limitation, computing device 704 may include at least one processing unit 720 that is operatively coupled to memory 722 through a bus 740 and a host or memory controller 715. Processing unit 720 is representative of one or more circuits configurable to perform at least a portion of a data computing procedure or process. By way of example but not limitation, processing unit 720 may include one or more processors, controllers, microprocessors, microcontrollers, application specific integrated circuits, digital signal processors, programmable logic devices, field programmable gate arrays, and the like, or any combination thereof. Processing unit 720 may communicate with memory controller 715 to process memory-related operations, such as read, write, and/or erase, as well as memory partition processes discussed above, for example. Processing unit 720 may include an operating system configured to communicate with memory controller 715. Such an operating system may, for example, generate commands to be sent to memory controller 715 over bus 740. Such commands may include instructions to partition at least a portion of memory 722, to associate one or more attributes to particular partitions, and to program a particular partition based at least in part on the type of data to be programmed and stored, for example.

Memory 722 is representative of any data storage mechanism. Memory 722 may include, for example, a primary memory 724 and/or a secondary memory 726. In a particular embodiment, memory 722 may comprise memory that may be partitioned based at least in part on one or more attributes of the memory and/or a memory management process, as described above. Primary memory 724 may include, for example, a random access memory, read only memory, etc. While illustrated in this example as being separate from processing unit 720, it should be understood that all or part of primary memory 724 may be provided within or otherwise co-located/coupled with processing unit 720.

Secondary memory 726 may include, for example, the same or similar type of memory as primary memory and/or one or more data storage devices or systems, such as, for example, a disk drive, an optical disc drive, a tape drive, a solid state memory drive, etc. In certain implementations, secondary memory 726 may be operatively receptive of, or otherwise configurable to couple to, a computer-readable medium 728. Computer-readable medium 728 may include, for example, any medium that can carry and/or make accessible data, code and/or instructions for one or more of the devices in system 700.

Computing device 704 may include, for example, an input/output 732. Input/output 732 is representative of one or more devices or features that may be configurable to accept or otherwise introduce human and/or machine inputs, and/or one or more devices or features that may be configurable to deliver or otherwise provide for human and/or machine outputs. By way of example but not limitation, input/output device 732 may include an operatively configured display, speaker, keyboard, mouse, trackball, touch screen, data port, etc.

In the above detailed description, numerous specific details are set forth to provide a thorough understanding of claimed subject matter. However, it will be understood by those skilled in the art that claimed subject matter may be practiced without these specific details. In other instances, methods, apparatuses, or systems that would be known by one of ordinary skill have not been described in detail so as not to obscure claimed subject matter.

Some portions of the detailed description above are presented in terms of algorithms or symbolic representations of operations on binary digital signals stored within a memory of a specific apparatus or special purpose computing device or platform. In the context of this particular specification, the term specific apparatus or the like includes a general purpose computer once it is programmed to perform particular operations pursuant to instructions from program software. Algorithmic descriptions or symbolic representations are examples of techniques used by those of ordinary skill in the signal processing or related arts to convey the substance of their work to others skilled in the art. An algorithm is here, and generally, is considered to be a self-consistent sequence of operations or similar signal processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a specific apparatus, such as a special purpose computer or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

The terms, “and,” “and/or,” and “or” as used herein may include a variety of meanings that will depend at least in part upon the context in which it is used. Typically, “and/or” as well as “or” if used to associate a list, such as A, B or C, is intended to mean A, B, and C, here used in the inclusive sense, as well as A, B or C, here used in the exclusive sense. Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments. Embodiments described herein may include machines, devices, engines, or apparatuses that operate using digital signals. Such signals may comprise electronic signals, optical signals, electromagnetic signals, or any form of energy that provides information between locations.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. A system comprising:
an error correction coding (ECC) decoder to receive signals representative of data read from a memory device and to determine a bit error rate and/or a number of bit errors associated with said read signals representative of said data; and
a remap controller to provide a remapped address of said memory device to a content-addressable memory (CAM) based at least in part on whether said bit error rate and/or said number of bit errors meets or exceeds an error threshold.

2. The system of claim 1, wherein said CAM is adapted to receive a read address and to transmit a signal responsive, at least in part, to whether said read address corresponds to said remapped address stored in said CAM.

3. The system of claim 2, further comprising:
a selection portion to select either said read address or said remapped address to be used as an address to read from said memory device, wherein said selection is based, at least in part, on said signal.

4. The system of claim 1, wherein said memory device comprises a main memory portion and a spare memory portion, and wherein said remapped address corresponds to a memory location in said spare memory portion.

5. The system of claim 4, wherein said memory device further comprises said ECC decoder and a phase-change memory portion.

6. The system of claim 1, wherein said bit error rate and/or said number of bit errors is responsive, at least in part, to a physical degradation of said memory.

7. A method comprising:
determining a bit error rate and/or a number of bit errors associated with signals representative of data read from a memory device;
providing a remapped address of said memory device to a content-addressable memory (CAM) based at least in part on whether said bit error rate and/or said number of bit errors meets or exceeds an error threshold; and
storing signals representative of said remapped address in said CAM.

8. The method of claim 7, further comprising:
receiving a read address; and
transmitting a signal responsive, at least in pair, to whether said read address corresponds to said remapped address stored in said CAM.

9. The method of claim 8, further comprising:
selecting either said read address or said remapped address to be used as an address to read from said memory device, wherein said selecting is based, at least in part, on said transmitted signal.

10. The method of claim 7, further comprising retiring a portion of said memory device corresponding to said remapped address.

11. The method of claim 10, wherein said retiring said portion of said memory device comprises:
relocating information represented by electronic signals from said portion of said memory device to another portion of said memory device.

12. The method of claim 7, wherein said memory device comprises a main memory portion and a spare memory portion, and wherein said remapped address corresponds to a memory location in said spare memory portion.

13. The method of claim 12, wherein said memory device further comprises said ECC decoder and a phase-change memory portion.

14. The method of claim 7, wherein said bit error rate and/or said number of bit errors is responsive, at least in part, to a physical degradation of said memory.

15. A system comprising:
a processor to transmit a read request;
an error correction coding (ECC) decoder to receive signals representative of data read from a memory device and to determine a bit error rate and/or a number of bit errors associated with said read signals representative of said data in response to said read request; and
a remap controller to provide a remapped address of said memory device to a content-addressable memory (CAM) based at least in part on whether said bit error rate and/or said number of bit errors meets or exceeds an error threshold.

16. The system of claim 15, wherein said CAM is adapted to receive a read address from said processor and to transmit a signal responsive, at least in part, to whether said read address corresponds to said remapped address stored in said CAM.

17. The system of claim 16, further comprising:
a selection portion to select either said read address or said remapped address to be used as an address to read from said memory device, wherein said selection is based, at least in part, on said signal.

18. The system of claim 15, wherein said memory device comprises a main memory portion and a spare memory portion, and wherein said remapped address corresponds to a memory location in said spare memory portion.

19. The system of claim 18, wherein said memory device further comprises said ECC decoder and a phase-change memory portion.

20. The system of claim 15, wherein said bit error rate and/or said number of bit errors is responsive, at least in part, to a physical degradation of said memory.
